(19) United States
(12) Patent Application Publication
(10) Pub. No.: US 2011/0022808 A1
(43) Pub. Date: Jan. 27, 2011

(54) OUTPUT DRIVER, MEMORY HAVING OUTPUT DRIVER, MEMORY CONTROLLER, AND MEMORY SYSTEM

(75) Inventors: Katsuhiro KITAGAWA, Tokyo (JP); Hiroshi ICHIKAWA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/836,201

(22) Filed: Jul. 14, 2010

(30) Foreign Application Priority Data
Jul. 21, 2009 (JP) 2009-169659

(51) Int. Cl. G06F 12/00; G11C 7/00; H03B 1/00

(52) U.S. Cl. 711/154; 365/191; 327/108; 711/E12.001

(57) ABSTRACT

An output driver has a first driver connected between a first power source and an output terminal and a second driver connected between a second power source and the output terminal. One of the first driver and the second driver has two driving parts connected in parallel to each other. The two driving parts and the other of the first driver and the second driver are operated by independent input signals.

This application is based upon and claims the benefit of priority from Japanese patent application No. 2009-169659, filed on Jul. 21, 2009, the disclosure of which is incorporated herein in its entirety by reference.

### BACKGROUND

1. Field of the Invention

The present invention relates to an output driver, and more particularly to an output driver used for a memory system.

2. Description of the Related Art

Various types of DRAM products subsequent to a double data rate synchronous dynamic random access memory (DDR SDRAM) are configured to use data strobe signals (DQS signals) to notify a receiver of timing of transfer when data are to be transferred between a memory and a memory controller. The DQS signal includes a preamble and a body following the preamble (clocking part). See, e.g., JP-A 2009-37287.

A related output driver used for outputting a DQS signal is formed by a CMOS inverter. See, e.g., JP-A 2008-198356.

### SUMMARY

The body of a DQS signal is formed by a signal having a high level and a low level repeated with a predetermined period. The preamble of a DQS signal is formed by a signal having a continuous low level. Therefore, when the preamble of a DQS signal is outputted, a potential of an output terminal gradually decreases and becomes lower than a potential of the output terminal at the time when the body of the DQS signal outputted has a low level. As a result, the first high-level interval following the preamble becomes shorter than high-level intervals that appear repeatedly after the first high-level interval.

The present invention seeks to solve one or more of the above problems, or to improve upon those problems at least in part.

In one embodiment, an output driver comprises a first driver connected between a first power source and an output terminal and a second driver connected between a second power source and the output terminal. One of the first driver and the second driver has two driving parts connected in parallel to each other. The two driving parts and the other of the first driver and the second driver are operated by independent input signals.

### BRIEF DESCRIPTION OF THE DRAWINGS

The above features and advantages of the present invention will be more apparent from the following description of certain preferred embodiments taken in conjunction with the accompanying drawings, in which

FIG. 1 is a block diagram showing a schematic arrangement of a memory system according to a first embodiment of the present invention.

FIG. 2 is a block diagram showing a schematic arrangement of a DQS output buffer used in the memory system of FIG. 1.

FIG. 3 is a waveform chart explanatory of a DQS signal and a DQ signal.

FIG. 4 is a waveform chart of a DQS signal outputted from a related DQS output driver.

FIG. 5 is a diagram explanatory of operation of the DQS output buffer shown in FIG. 2.

### DESCRIPTION OF EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

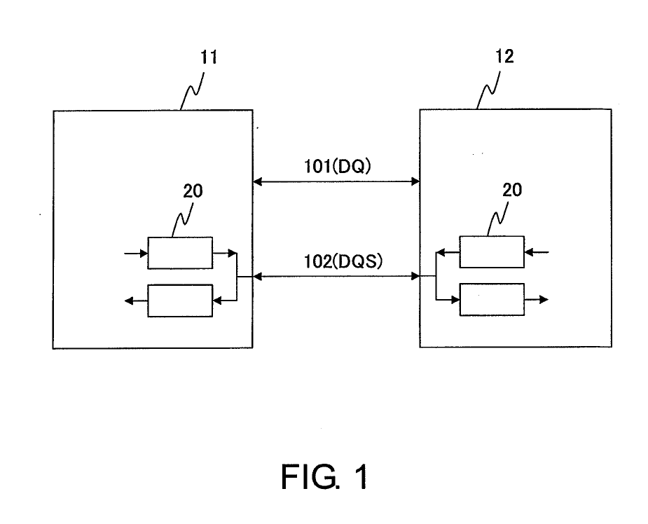

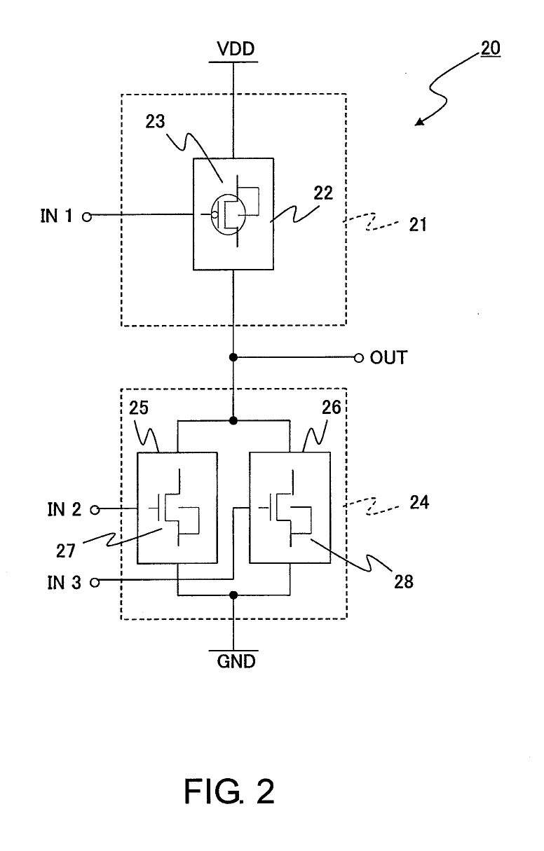

Referring to FIGS. 1 to 5, an exemplary embodiment of the present invention will be described below.

As shown in FIG. 1, a memory system according to a first embodiment of the present invention includes a memory 11 and a memory controller 12. The memory 11 is formed of a semiconductor memory device such as a dynamic random access memory (DRAM).

Data (DQ) 101 are transferred between the memory 11 and the memory controller 12. In order to transfer those data 101, data strobe signals (DQS) 102 are also transferred between the memory 11 and the memory controller 12. Therefore, each of the memory 11 and the memory controller 12 has a DQS output driver 20 for transmitting the data strobe signal 102.

The DQS output driver 20 includes a first driver (pull-up driver) 21 connected between a first power source VDD and an output terminal OUT. The first driver 21 has a driving part 22 of a p-type metal oxide semiconductor field effect transistor (pMOSFET) 23, which is hereinafter simply referred to as a pMOS transistor. The DQS output driver 20 also includes a second driver (pull-down driver) 24 connected between a second power source GND and the output terminal OUT. The second driver 24 has two driving parts 25 and 26 of n-type metal oxide semiconductor field effect transistors (nMOSFETs) 27 and 28, which are hereinafter simply referred to as nMOS transistors. Those driving parts 25 and 26 are connected in parallel to each other. Independent DQS base signals are supplied as input signals to the pMOS transistor 23, the nMOS transistor 27, and the nMOS transistor 28 via input terminals IN-1, IN-2, and IN-3, respectively.

The DQS output driver 20 is configured such that a rise time of an output signal is equal to a fall time of the output signal. Specifically, the DQS output driver 20 is configured such that the swing capability at the time when the two nMOS transistors 27 and 28 are simultaneously operated is balanced with the swing capability of the pMOS transistor 23. The term “swing capability” means the magnitude of a time-varying output level at the time when the pMOS transistor 23 or the nMOS transistors 27 and 28 are turned on under certain conditions of use.

Furthermore, one of the nMOS transistors (the nMOS transistor 28 in this example) is configured so as to have predetermined swing capability when it is solely operated. Specifically, the nMOS transistor 28 is configured such that an output level of the nMOS transistor 28 at the time when a period of time corresponding to the preamble period has elapsed since the nMOS transistor 28 was solely turned on is equal to an output level of the nMOS transistor 28 at the end of a low-level interval of the clocking operation. This configuration can be implemented by, for example, making the channel width of the nMOS transistor smaller than the channel width of an nMOS used for a related DQS output driver. It is preferable to set the channel width of the nMOS transistor 27 to be smaller than the channel width of the nMOS transistor 28.

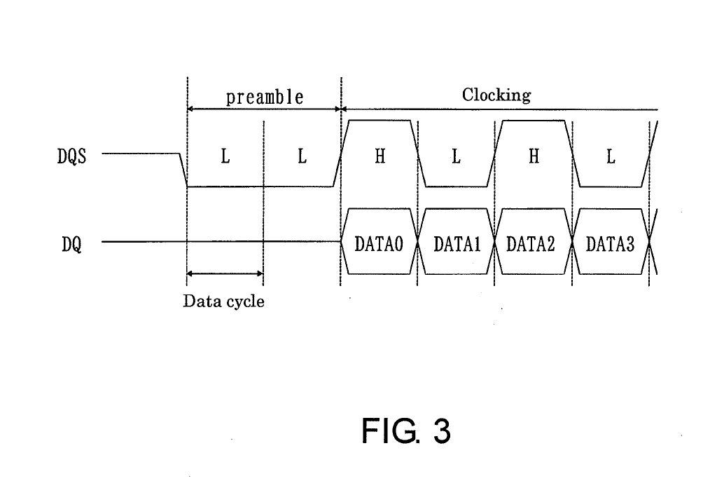

As shown in FIG. 3, the DQS signal includes a preamble and a clocking part as a body of the DQS signal. The preamble is formed by a signal having a low level “L” continuing for two data cycles. The clocking part is formed by a signal having a high level “H” and a low level “L” alternately repeated. A receiver detects the preamble so as to know the start of transfer of data (DQ). Furthermore, the receiver uses rise edges and fall edges of the clocking part so as to know boundaries of the data signal.

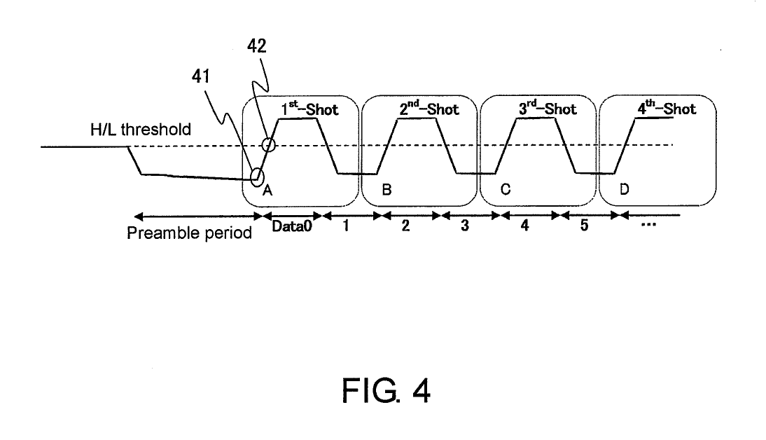

FIG. 4 is a waveform chart of a DQS signal outputted from a related DQS output driver. As is apparent from FIG. 4, an output level of the output driver is continuously decreased during the preamble period. Because the preamble period is (about twice) longer than each of low-level periods of the clocking part, a potential of a rise edge A (encircled portion 41) at the end of the preamble period is lower than potentials of rise edges B, C, and D of the clocking part. This result is also affected by the fact that a potential at the beginning of the preamble is not at a high level (but at an intermediate level).

Thus, in the related DQS output driver, the potential of the rise edge A is lower than the potentials at the rise edges B to D. Therefore, a period of time required for the first pulse (first-shot) to exceed a threshold (H/L threshold) between a high level and a low level (encircled portion 42) is longer than a period of time required for each of pulses following the first pulse (second-shot, third-shot, fourth-shot, and so forth) to exceed the H/L threshold. As a result, a high-level period of the first pulse is shorter than a high-level period of each of the following pulses. Therefore, jitter is caused to the DQS signal.

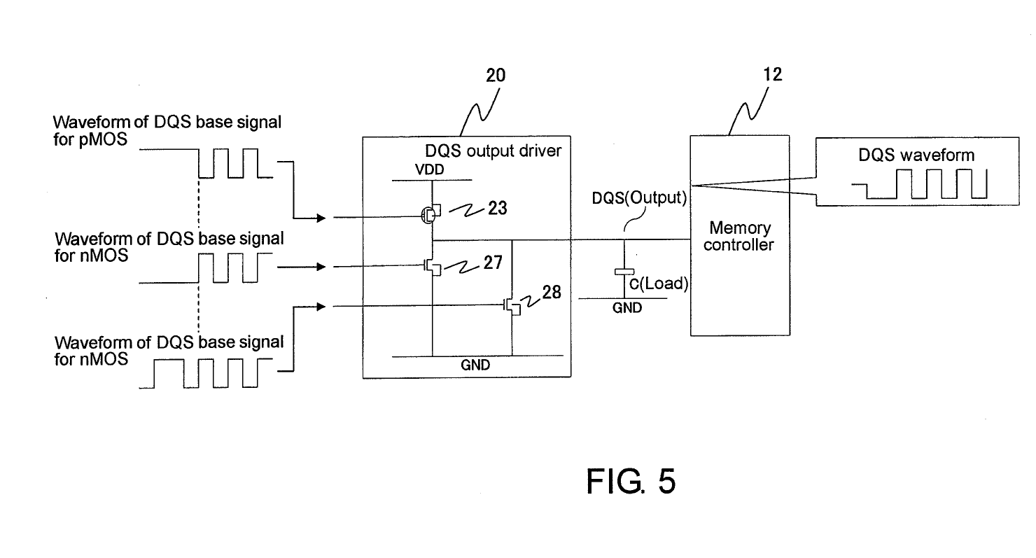

The DQS output driver according to the present embodiment can reduce such a potential variation during the preamble period and can thus suppress the jitter. Operation of the DQS output driver according to the present embodiment will be described below with reference to FIG. 5. The following description is focused on the DQS output driver of the memory 11. However, the following description can also be applied to the DQS output driver of the memory controller 12.

As shown in FIG. 5, independent input signals are respectively supplied to the pMOS transistor 23 and the nMOS transistors 27 and 28. Those input signals can readily be obtained by processing original signals with a simple logical circuit or the like.

The input signal supplied to the pMOS transistor 23 (the DQS base signal for the pMOS) turns the pMOS transistor 23 on during the preamble period and repeatedly turn the pMOS transistor 23 on and off in an alternate manner during the clocking period. This operation is the same as operation of a pull-up driver of the related DQS output driver.

The input signal supplied to the nMOS transistor 27 (the DQS base signal for a first nMOS) turns the nMOS transistor 27 off during the preamble period and repeatedly turns the nMOS transistor 27 on and off during the clocking period. The nMOS transistor 27 is turned on during the clocking period when the pMOS transistor 23 is turned off. Conversely, the nMOS transistor 27 is turned off during the clocking period when the pMOS transistor 23 is turned on.

The input signal supplied to the nMOS transistor 28 (the DQS base signal for a second nMOS) turns the nMOS transistor 28 on during the preamble period and repeatedly turns the nMOS transistor 28 on and off during the clocking period. The nMOS transistor 28 is turned on during the clocking period when the nMOS transistor 27 is turned on. The nMOS transistor 28 is turned off during the clocking period when the nMOS transistor 27 is turned off. This operation is the same as operation of a pull-down driver of the related DQS output driver.

With the aforementioned input signals supplied to the pMOS transistor 23 and the nMOS transistors 27 and 28, the nMOS transistor 28 is turned on, and the pMOS transistor 23 and the nMOS transistor 27 are turned off during the preamble period. Since the nMOS transistor 28 has relatively low swing capability, an output potential dully decreases. Therefore, an output potential at the end of the preamble period becomes almost the same as an output potential at the end of each of the low-level intervals of the clocking period. Operation of turning the pMOS transistor 23 on and turning the nMOS transistors 27 and 28 off and operation of turning the pMOS transistor 23 off and turning the nMOS transistors 27 and 28 on are alternately repeated after the preamble period. The waveform of the output signal during the clocking period is substantially the same as a waveform outputted from the related output driver.

In FIG. 5, the output signals are illustrated as square waves. Practically, however, it takes time to rise and fall the signal because a transmission line or the like has a parasitic capacitance (load) C. Therefore, the actual output signals are trapezoid waves.

Thus, the DQS output driver according to the present embodiment can prevent decrease of the output potential during the preamble period, so that the length of the high-level interval of the first pulse after the preamble period can be made equal to the length of the high-level intervals of the following pulses.

According to the present embodiment, two driving parts connected in parallel to each other are operated in accordance with independent input signals. Therefore, the swing capability of the first or second driver including those two driving parts can be made variable. When a preamble is outputted, the swing capability is lowered so as to reduce the variation of the output potential during the preamble period. Accordingly, a signal waveform of a body following the preamble can be improved.

The present invention has been described based upon the illustrated embodiment. Nevertheless, the present invention is not limited to the aforementioned embodiment. For example, in the above embodiment, the first driver 21 has one driving part, whereas the second driver 24 has two driving parts. However, if the preamble is formed by a signal having a continuous high level, then the second driver 24 may have one driving part while the first driver 21 has at least two driving parts. Furthermore, three or more driving parts may be provided in the first driver 21 or the second driver 24 so as to selectively use driving parts that exhibit appropriate characteristics. In the above embodiment, the output driver outputs a DQS signal. However, the present invention is also applicable to an output buffer that outputs a signal having a preamble continuously holding the same voltage level and a clocking part following the preamble as in the case of the DQS signal. In the above embodiment, MOSFETs are used for the driving parts. However, other types of transistors may be used for those driving parts.

What is claimed is:

1. An output driver, comprising:
a first driver connected between a first power source and an output terminal; and
a second driver connected between a second power source and the output terminal;
wherein one of the first driver and the second driver has two driving parts connected in parallel to each other,
wherein the two driving parts and the other of the first driver and the second driver are operated by independent input signals.

2. The output driver as recited in claim 1, wherein the two driving parts have different swing capabilities.

3. The output driver as recited in claim 1, wherein an output signal having a preamble and a body following the preamble is supplied to the output terminal.

4. The output driver as recited in claim 3, wherein the output signal comprises a DQS signal transferred between a memory and a memory controller for controlling the memory.

5. The output driver as recited in claim 1, wherein each of the two driving parts includes one of a pMOS transistor and an nMOS transistor,
wherein the other of the first driver and the second driver includes the other of the pMOS transistor and the nMOS transistor.

6. A memory, comprising:
an output driver;
wherein the output driver comprises;
a first driver connected between a first power source and an output terminal; and
a second driver connected between a second power source and the output terminal,
wherein one of the first driver and the second driver has two driving parts connected in parallel to each other,
wherein the two driving parts and the other of the first driver and the second driver are operated by independent input signals.

7. The memory as recited in claim 6, wherein the two driving parts have different swing capabilities.

8. The memory as recited in claim 6, wherein an output signal having a preamble and a body following the preamble is supplied to the output terminal.

9. The memory as recited in claim 8, wherein the output signal comprises a DQS signal transferred between the memory and a memory controller for controlling the memory.

10. The memory as recited in claim 6, wherein each of the two driving parts includes one of a pMOS transistor and an nMOS transistor,
wherein the other of the first driver and the second driver includes the other of the pMOS transistor and the nMOS transistor.

11. A memory controller, comprising:
an output driver;
wherein the output driver comprises;
a first driver connected between a first power source and an output terminal; and
a second driver connected between a second power source and the output terminal,
wherein one of the first driver and the second driver has two driving parts connected in parallel to each other,
wherein the two driving parts and the other of the first driver and the second driver are operated by independent input signals.

12. The memory controller as recited in claim 11, wherein the two driving parts have different swing capabilities.

13. The memory controller as recited in claim 11, wherein an output signal having a preamble and a body following the preamble is supplied to the output terminal.

14. The memory controller as recited in claim 13, wherein the output signal comprises a DQS signal transferred between the memory and a memory controller for controlling the memory.

15. The memory controller as recited in claim 11, wherein each of the two driving parts includes one of a pMOS transistor and an nMOS transistor,
wherein the other of the first driver and the second driver includes the other of the pMOS transistor and the nMOS transistor.

16. A memory system, comprising:
a memory; and
a memory controller;
wherein at least one of the memory and the memory controller comprises an output driver as recited in claim 1.

17. The memory system as recited in claim 16, wherein the two driving parts have different swing capabilities.

18. The memory system as recited in claim 16, wherein an output signal having a preamble and a body following the preamble is supplied to the output terminal.

19. The memory system as recited in claim 18, wherein the output signal comprises a DQS signal transferred between the memory and a memory controller for controlling the memory.

20. The memory system as recited in claim 16, wherein each of the two driving parts includes one of a pMOS transistor and an nMOS transistor,
wherein the other of the first driver and the second driver includes the other of the pMOS transistor and the nMOS transistor.
